(19) United States
(12) Patent Application Publication
(10) Pub. No.: US 2006/0267486 A1
(43) Pub. Date: Nov. 30, 2006

(54) Full color organic electroluminescent display device and method for manufacturing the same

(76) Inventors: Chien-Yuan Feng, Chu-Nan (TW); Sheng-Hsu Shih, Chu-Nan (TW); Wen-Jeng Lan, Chu-Nan (TW); Chien-Chih Chiang, Chu-Nan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/195,628

(22) Filed: Aug. 3, 2005

(30) Foreign Application Priority Data
May 30, 2005 (TW) 094117723

(51) Int. Cl. H01J 1/62; H01J 63/04

(52) U.S. Cl. 313/504

(57) ABSTRACT

A full color organic electroluminescent display device and a method of manufacturing the same are provided. The display device provides a lower electrode on an upper surface of a color filter, and respectively providing a first organic light emitting unit capable of generate a first color light and a fourth organic light emitting unit capable of generating a fourth color light on an upper surface of the lower electrode. Among them, the first organic light emitting unit is at a vertically extended position of a first color photoresist of the color filter, and the first color light can pass through the first color photoresist to be filtered to generate the first color light with the same color; while the fourth organic light emitting unit is simultaneously at a vertically extended position of a second color photoresist and third color photoresist of the color filter, and the fourth color light can be filtered to generate a second color light when passing through the second color photoresist and a third color light when passing through the third color photoresist, respectively. By mixing and collocating the first color light, second color light, and third color light, a full color light emitting function is formed.

### FIELD OF THE INVENTION

The present invention relates to an organic electroluminescent display device, and more particularly to a full color organic electroluminescent display device and a method of manufacturing the same, which effectively improve transport of light source and color saturation, as well as improve yield by such a simplified process.

### BACKGROUND

In various displays, how to achieve the technology with full color display effect is always the key whether the display development succeeds or not. For organic electroluminescent (OEL) display device or organic light-emitting diodes (OLED), the two common ways to achieve the full color display function are:

1. Independently position organic electroluminescent display elements capable of generating three primary colors, i.e. red (R), green (G), and blue (B), respectively. Mix and collocate such three-color light to generate full color display effect. However, since repeated evaporation processes are needed to generate organic light emitting units with different color light in manufacturing such an organic electroluminescent display device, the manufacturing process is more minute and complicated, as well as the accuracy in evaporating and aligning is difficult. Therefore, yield is reduced and manufacturing cost is relatively raised.

2. Place at least one organic electroluminescent display device capable of emitting white light source as a poor light source. Collocate with highly skilled color filter. Achieve an object of filtering light color of the white light source by using the color filter, and thus generating full color display effect.

The organic electroluminescent display device generally using a color filter to proceed filtering light color is shown in FIG. 1. The color filter 10 mainly provides a black matrix 13 on a light perviousness substrate 11 and a color filtering layer 15, which comprises a first color photoresist (R) 151, second color photoresist (G) 153, and third color photoresist (B) 155, on an upper surface of the substrate 11 without the black matrix 13. Further, an overcoat or a barrier 19 can be selectively provided above the black matrix 13 and color filtering layer 15 to be beneficial to proceeding the follow-up process.

In addition, a lower electrode 21 of an organic electroluminescent display element 20 is directly provided on an upper surface of a barrier 19 or an overcoat 17, and an organic light emitting unit 23 and a second electrode 25 are provided in order on a partial upper surface of the lower electrode 21. Through working current of the lower electrode 21 and second electrode 25 guided, the organic light emitting 23 projects a white light source L. After the white light source L passing through the color filtering layer 15, an operation of filtering light color is proceeded to become three primary colors L1, L2, and L3, i.e. red (R), green (G), and blue (B). By collocating such a combination, an object of full color display of the organic electroluminescent display device 200 is achieved.

By using the color filter 10, such an OLED structure only needs an organic light emitting unit 23 capable of generating white light source, and thus needs fewer evaporation processes. Therefore, the evaporation frequency of the organic light emitting unit 23 can be effectively reduced, and the difficulty of accurately alignment in evaporating is relatively reduced. However, since the wavelength of the white light source L distributes more widely such that the ratio of penetration of the white light source L to the color filtering layer 15 is not good to further affect light emitting brightness and light color saturation of the organic electroluminescent display device 200. Therefore, the light emitting quality cannot be improved.

### SUMMARY OF THE INVENTION

Accordingly, how to design a novel organic electroluminescent display device and a method of manufacturing the same with respect to the previous mentioned problems encountered by the previous mentioned prior art to effectively reduce steps of processes and difficulty in aligning, have effects of improving light source penetration ratio and light color saturation thereof, reduce consumption of light emitting power, and extend lifetime of elements is the key point of the present invention.

It is a primary object of the present invention to provide a full color organic electroluminescent display device, which achieves an effect of full color display by fewer frequency evaporation processes. It simplifies the manufacturing flows as well as relatively reduces the aligning accuracy difficulty in evaporating, and thus effectively improve the yield.

It is a secondary object of the present invention to provide a full color organic electroluminescent display device which effectively improves light source penetration ratio of organic light emitting units and increase light color saturation thereof.

It is another object of the present invention to provide a method of manufacturing of a full color organic electroluminescent display device which simplifies the manufacturing flows, reduces the accuracy difficulty in aligning, effectively improves light source penetration ratio and light color saturation of organic light emitting units, thus reduces consumption of light emitting power, and extend lifetime of elements.

It is another object of the present invention to provide a full color organic electroluminescent display device, which has better color appearance by using color filter to embellish. It is easier and more convenient to adjust the light emitting color. A problem of color deviation and bad color saturation caused by unevenly declination of light emission of three colors, i.e. red, blue, and green (SBS), can be avoided, and thus the color appearance can be effectively kept.

To achieve the previous mentioned objects, the present invention provides a full color organic electroluminescent display device whose main structure comprises: a color filter mainly providing a first color photoresist, a second color photoresist, and a third color photoresist on an upper surface of a substrate and providing an overcoat on an upper surface thereof; at least one lower electrode provided on a partial upper surface of the color filter; a first organic light emitting unit provided on an upper surface of the lower electrode at a vertically extended position of the first color photoresist and being able to generate a first color light; a fourth organic light emitting unit provided on an upper surface of the lower electrode at a vertically extended position of the second color photoresist and the third color photoresist and being able to generate a fourth color light with a complementary characteristic of the first color light; and at least one second electrode provided on upper surfaces of the first organic light emitting unit and the fourth organic light emitting unit.

Further, to achieve the previous mentioned objects, the present invention further provides a method of manufacturing a full color organic electroluminescent display device mainly comprising the steps of: forming at least one lower electrode on a partial upper surface of a color filter; placing a first mask at a vertically extended position of the second color photoresist and third color photoresist of the color filter; using a first evaporation source to an upper surface of the lower electrode at a vertically extended position of the first color photoresist to form an organic light emitting layer with a first organic light emitting unit capable of generating a first color light; placing a second mask at a vertically extended position of the first organic light emitting unit, and then using a second evaporation source to an upper surface of the lower electrode at a vertically extended position of the second color photoresist and the third color photoresist to form an organic light emitting layer with a fourth organic light emitting unit capable of generating a fourth color light; and forming at least one second electrode on upper surfaces of the first organic light emitting unit and fourth organic light emitting unit.

### BRIEF DESCRIPTION OF DRAWINGS

FIG. 1 is a sectional diagram of a prior art organic electroluminescent display device.

FIG. 2 is a sectional diagram of a preferred embodiment of an organic electroluminescent display device of the present invention.

FIG. 3A and FIG. 3B are respectively sectional diagrams in each step of the process of a preferred embodiment of the present invention.

FIG. 4 is a sectional diagram of an alternate embodiment of the present invention.

FIG. 5 is a sectional diagram of an alternate embodiment of the present invention.

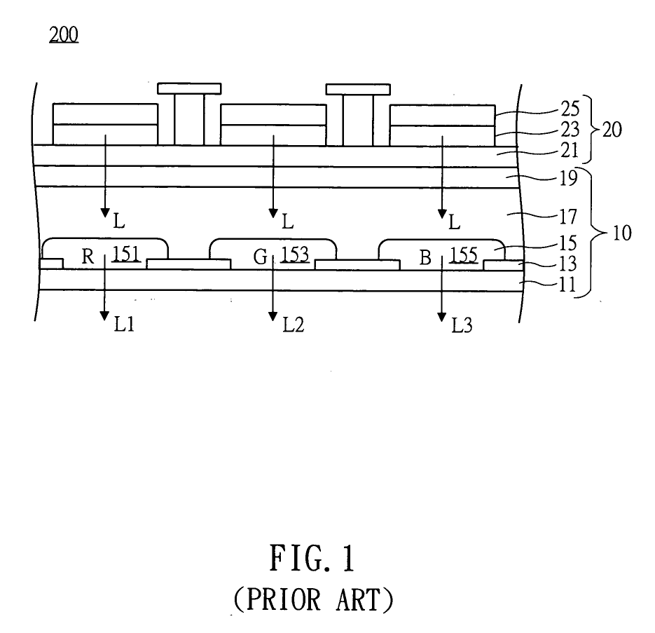

### DETAILED DESCRIPTION

The structural features and the effects to be achieved may further be understood and appreciated by reference to the presently preferred embodiments together with the detailed description.

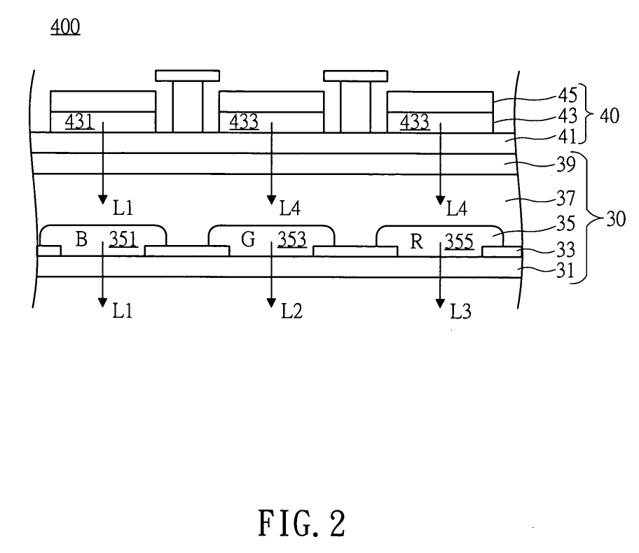

Firstly, refer to FIG. 2, a sectional diagram of a preferred embodiment of an organic electroluminescent display device of the present invention. As shown, the organic electroluminescent (OLED) display device 400 mainly provides at least one organic electroluminescent (OLED) display element 40 on an upper surface of a color filter 30. The color filter 30 mainly provides at least one black matrix 33 on a partial upper surface of a light perviousness substrate 31 and further provides a color filtering layer 35, which mainly comprises a first color photoresist (B) 351, second color photoresist (G) 353, and third color photoresist (R) 355, with a light color filtering function on the upper surface of the substrate 31 with the black matrix 33. Further, an overcoat barrier unit can be covered above the black matrix 33 and color filtering layer 35, such as an overcoat 37, a barrier 39, or both.

At least one lower electrode 41 of the OLED element 40 is provided in a partial area of an upper surface of the barrier 39 (or overcoat 37) of the color filter 30, and an organic light emitting unit 43 and a second electrode 45 are provided in order on a partial upper surface of the lower electrode 41. The organic light emitting unit 43 comprises at least one first organic light emitting unit 431 and at least one-fourth organic light emitting unit 433. When working current is supplied between the lower electrode 41 and the second electrode 45, the first organic light emitting unit 431 and fourth organic light emitting unit 433 will respectively generate a first color light L1 and a fourth color light L4, and the first color light L1 and fourth color light L4 are complementary color light to each other.

The first organic light emitting unit 431 is provided at a vertically extended position of the first color photoresist 351, and the fourth organic light emitting unit 433 is simultaneously provided at vertically extended positions of the second color photoresist 353 and third color photoresist 355. This way, the first color light L1 generated by the first organic light emitting unit 431 can directly pass through the first color photoresist 351 and be filtered to generate first color light L1 with the same light color. The fourth color light L4 generated by the fourth organic light emitting unit 433 is filtered to generate corresponding second color light L2 and third color light L3 after passing through the second color photoresist 353 and third color photoresist 355. By mixing and collocating the first color light L1, second color light L2, and third color light L3, a full color display effect is achieved.

For example, the first color light L1 generated by the first organic light emitting unit 431 is a blue light source, and the fourth color light L4 generated by the fourth organic light emitting unit 433 is an organic light source. Besides, the first color photoresist 351, second color photoresist 353, and third color photoresist 355 are respectively a blue photoresist B (351), green photoresist G (353), and red photoresist R (355) or a blue photoresist B (351), red photoresist R (355), and green photoresist G (353). Therefore, the first color light L1 (blue light) still remains the light color of the first color light L1 (blue light) after passing through the filter of the first color photoresist (blue photoresist) 351; while the fourth color light L4 (orange light) is respectively filtered to a second color light L2 (green light) and a third color light L3 (red light) after passing through the second color photoresist (green photoresist) 353 and third color photoresist (red photoresist) 355. By the complementarity and mixed collocation with a prior ratio of the first color light L1 (blue light), second color light L2 (green light), and third color light L3 (red light), an object of full color display of the OLED device 400 can be achieved.

Of course, in an alternate embodiment of the present invention, the first color light L1 generated by the first organic light emitting unit 431 can also be a red light source, while the fourth color light L4 generated by the fourth organic light emitting unit 433 can be a blue green light source. Correspondingly, the first color photoresist 351, second color photoresist 353, and third color photoresist 355 are respectively a red photoresist, a green photoresist, and a blue photoresist or a red photoresist, a blue photoresist, and a green photoresist. The same object of full color display of the OLED device 400 can also be achieved as well.

The color-filtering layer 35 is a device only allowing light source with a wavelength within a specified range to pass through, and an object of filtering light color is thus achieved. For instance, if the first color photoresist 351 is designed to allow the light source with a wavelength range between 400 nm˜500 nm, it means after a poor light source, such as the white light source L in the prior art structure, passing through the first color photoresist 351, the first color photoresist 351 filters and blocks color light sources other than the wavelength range between 400 nm˜500 nm and prevents them from passing through such that the wavelength range of the color light passing through the first color photoresist 351 is between 400 nm˜500 nm, i.e. blue light source which is able to be sensed by naked eyes, and an object of filtering light color is thus achieved. However, in the meantime of filtering light color, the color light sources other than the wavelength range between 400 nm˜500 nm is filtered and blocked by the first color photoresist 351. Therefore, for the white light source L, the first color photoresist 351 does not have good light source penetration ratio, about 25%, and the light brightness thereof is also relatively reduced.

On the other hand, if the wavelength distribution range of the first color light L1 is in the wavelength range which is allowed to pass through by the first color photoresist 351, it means for the first color light L1, the first color photoresist 351 has a good light source penetration ratio. For instance, if the wavelength distribution range of the first color light L1 is 420 nm˜470 nm (blue light source), and the wavelength range which is allowed to pass through by the first color photoresist 351 is 400 nm˜500 nm (blue photoresist), then most of the first color light L1 can completely pass through the first color photoresist 351. For example, in an embodiment of the present invention, the light source penetration ratio is up to 80%. Therefore, in opposition to the OLED device (200) using the white light source L as a poor light source, the present invention has better light source penetration ratio and light brightness, and of course relatively effectively reduces power consumption and extends lifetime of elements.

Further, if the fourth color light L4 is an orange light source, and the collocated second color photoresist 353 and third color photoresist 355 are respectively a green photoresist and a red photoresist, since the fourth color light L4 (orange light source) is mainly mixed by green light source and red light source with a proper ratio, the fourth color light L4 (orange light source) is respectively filtered and blocked the red light source and green light source of the fourth color light L4 (orange light source) and the second color light L2 (green light source) and third color light L3 (red light source) is respectively generated after passing through the second color photoresist (green photoresist) 353 and third color photoresist (red photoresist) 355. Now, for the fourth color light L4, the second color photoresist 353 and third color photoresist 355 has better light source penetration ratio than the prior art OLED device (200), such as up to 40%.

Therefore, by the user of the OLED device 400 of the present invention, the light source penetration ratio to the color filtering layer 35 of the first color light L1 and fourth color light L4 can be increased, and an object of improving the light source penetration ratio, light brightness, light color saturation of the OLED device 400, extending lifetime of elements, and reducing power consumption can be achieved.

In addition, in an alternate embodiment of the present invention, a light perviousness substrate (not shown) can be used to replace the color filter 30 of the previous mentioned embodiment. A first electrode 41 is provided in a partial area of an upper surface of the light perviousness substrate, and a first organic light emitting unit 431 and fourth organic light emitting unit 433 are provided on a partial upper surface of the first electrode 41 to respectively generate a first color light L1 and fourth color light L4. The first color light L1 and fourth color light L4 can be complementary color light to each other.

Since the first color light L1 and fourth color light L4 is complementary color light, by mixed collocation of the first color light L1 and fourth color light L4 with a prior ratio, an object of full color display of the OLED device 400. Further, since the first color light L1 and fourth color light L4 generated by the OLED device 400 does not need to be light filtered by the color filter 30, the brightness declination abuse caused in a process of the first color light L1 and fourth color light L4 passing through the color filter 30 can be avoided.

Further, the organic light emitting unit 43 can be a light emitting unit generating color light source through guiding current signals. Among them, the organic light emitting unit 43 can selectively comprise one of a hole injection layer (HIL), a hole transport layer (HTL), an organic emitting material layer (EML), an electron transport layer (ETL), an electron injection layer (EIL), and a combination thereof therein.

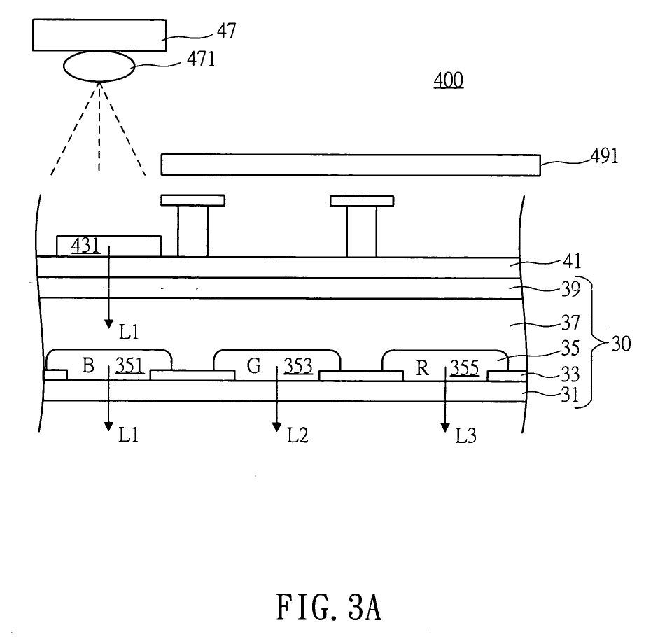

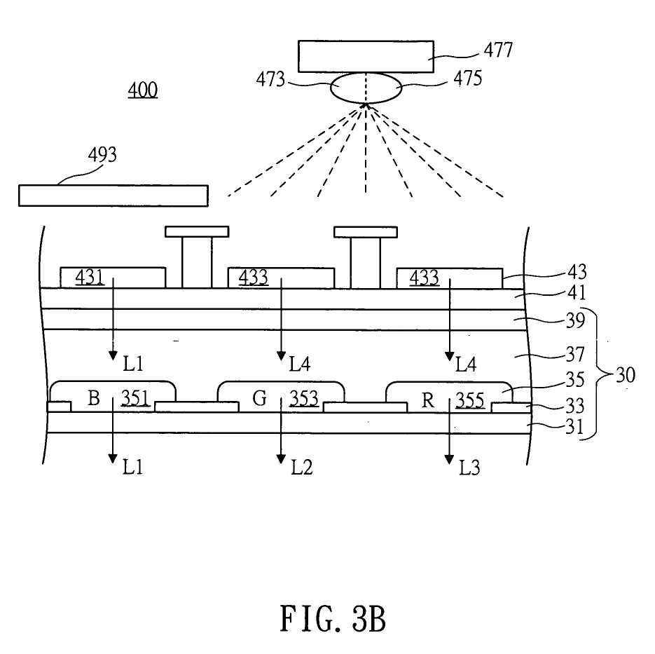

Furthermore, please refer to FIGS. 3A and 3B, respectively sectional diagrams in each step of the process of a preferred embodiment of the present invention. As shown, the manufacturing steps of the OLED device 400 of the present invention mainly provides at least one first organic light emitting unit 431 and at least one fourth organic light emitting unit 433 on the upper surface of the lower electrode 41 by the means of evaporation after completely providing the lower electrode 41 of the OLED device 400.

First, the organic light emitting layer of the first organic light emitting layer 431 covers and blocks the partial lower electrode 41 by the use of a first mask 491 and uses a first evaporation source 47 to proceed evaporating the organic light emitting layer of the first organic light emitting layer 431 against the upper surface of the partial lower electrode 41 uncovered by the first mask 491. For instance, traverse the first mask 491 to vertically extended positions of the second color photoresist 353 and third color photoresist 355, and then use the first evaporation source 47 to proceed a first evaporation process. This moment, the first evaporation source 47 only proceed evaporating to a vertically extended position of the first color photoresist 351 to form the organic light emitting layer of the first organic light emitting layer 431 at the vertically extended position of the first color photoresist 351. The first evaporation source 47 can be selected as a first organic light emitting material 471 capable of generating the first color light L1, such as derivation of TPAN, DPAN, DPVBi, PPD, Balq, or DSA capable of generating blue light, as shown in FIG. 3A.

After completely providing the organic light emitting layer of the first organic light emitting unit 431, place a second mask 493 at a vertically extended position of the first organic light emitting unit 431, and use a second evaporation source 477 to proceed a second evaporation process. Now, the organic light emitting layer of the fourth organic light emitting unit 433 is simultaneously formed at the vertically extended positions of the second color photoresist 353 and third color photoresist 355, as shown in FIG. 3B.

Further, since the fourth organic light emitting unit 433 can generate a fourth color light L4 which can pass through the second color photoresist (G) 353 and third color photoresist (B) 355, such as an orange light source, the second evaporation source 477 can directly use an orange organic light emitting material, such as DPP, or adulterate a second organic light emitting material 473 and a third organic light emitting material 475 by the means of mixed collocation, such as green organic light emitting material: derivatives of Alq, DPT, Alq3, C6 and red organic light emitting material: derivatives of DCM-2, DCJT.

Of course, in an alternate embodiment of the present invention, the second mask 493 can be provided at the vertically extended position of the first color photoresist 351 first, then proceed the evaporation of the organic light emitting layer of the fourth organic light emitting unit 433. In other words, that is to say proceed providing the organic light emitting layer of the first organic light emitting unit 431 after providing the organic light emitting layer of the fourth organic light emitting unit 433.

Further, the former process of the OLED device can be pre-proceeded before proceeding the evaporating step to provide the organic light emitting layer of the first organic light emitting unit 431 and the organic light emitting layer of the first organic light emitting unit 433. For instance, a hole injection layer or a hole transport layer is provided on the upper surface of the lower electrode 41, and the follow-up process of the OLED device 400 is continued after the completely follow-up providing the organic light emitting layer of the first organic light emitting unit 431 and the organic light emitting layer of the first organic light emitting unit 433. For example, an electron transport layer, an electron injection layer, and the second electrode 45 are provided above the organic light emitting layer of the first organic light emitting unit 431 and the organic light emitting layer of the first organic light emitting unit 433.

In the previous mentioned manufacturing flows, the evaporation frequency and alignment of the organic light emitting unit 43 is truly reduced in comparison with the prior art OLED device formed by independently providing organic electroluminescent display device with three primary colors, i.e. red (R), green (G), blue (B) and full color display effect can also be achieved as well. Further, by reducing the evaporation frequency, the accuracy request in alignment in evaporation can be effectively reduced, and the yield of the OLED device 400 is thus improved.

When the organic light emitting unit 43 comprises the structure of a hole injection layer, hole transport layer, organic emitting material layer, electron transport layer, and electron injection layer therein, the structure of the previous mentioned organic light emitting unit 43 can be formed in order on a partial upper surface of the lower electrode 41. For instance, the hole injection layer and hole transport layer are formed in order on the upper surface of the lower electrode 41 at the vertically extended position of the color photoresist 35 by the means of evaporation, and the organic light emitting layer of the first organic light emitting unit 431 is evaporated and formed on the upper surface of the hole transport layer on the vertically extended position of the first color photoresist 351, then the organic light emitting layer of the fourth organic light emitting unit 433 is evaporated and formed on the upper surface of the hole transport layer on the vertically extended positions of the second color photoresist 353 and third color photoresist 355, finally the electron transport layer and electron injection layer are formed in order on the upper surfaces of the organic light emitting layer of the first organic light emitting unit 431 and the organic light emitting layer of the fourth organic light emitting unit by the means of evaporation to thus complete providing the organic light emitting unit 43.

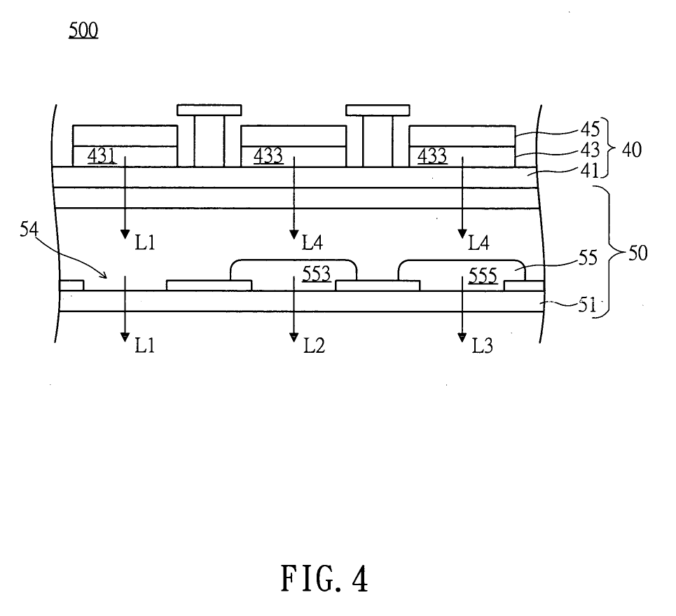

Continuously, please refer to FIG. 4, a sectional diagram of an alternate embodiment of the present invention. As shown, the organic electroluminescent (OLED) display device 500 of the present invention mainly provides at least one organic electroluminescent (OLED) display element 40 on the upper surface of a color filter 50. Among them, the color-filtering layer 55 of the color filter 50 only comprises at least one color photoresist 553 (such as green photoresist) and at least one third color photoresist 555 (such as red photoresist). No color photoresist is no longer provided at the position of the first color photoresist (351) provided in the previous mentioned embodiment. Accordingly, a hollowed part 54 is naturally formed. The formation of the hollowed part 54 can be selected when manufacturing the color filter 50 without further providing the first color photoresist (351).

The first color light L1 generated by the first organic light emitting unit 431 of the OLED element 40 directly passes through the substrate 51 to the exterior of the color filter 50 via the hollowed part 54 of the color filter 50; while the fourth color light L4 generated by the fourth organic light emitting unit 433 is still needed to be filtered to the second color light L2 (such as green light) and third color light L3 (such as red light) after respectively passing through the second color photoresist 553 and third color photoresist 555 of the color filtering layer 55. The same object of full color display of the OLED device 500 can also thus be achieved as well. Since the first color light L1 passes through the light perviousness substrate 51 of the color filter 50 via the hollowed part 54, the penetration ratio and color saturation of the first color light L1 can be improved, as well as the process steps of the color filter 50 and production cost can also be reduced.

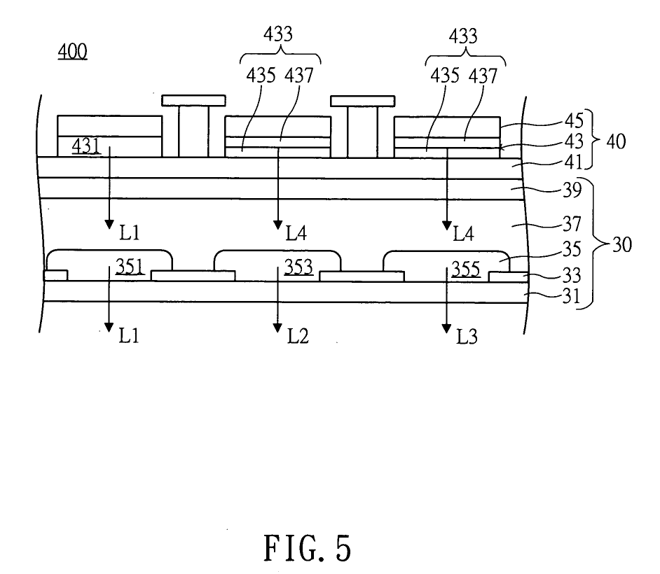

Finally, please refer to FIG. 5, a sectional diagram of an alternate embodiment of the present invention. As shown, in this embodiment, the fourth organic light emitting unit 433 comprises at least one second organic light emitting layer 435 and third organic light emitting layer 437 provided by the means of cascading to replace the way of mixed collocating different organic light emitting materials and simultaneously evaporating used in the previous mentioned embodiment.

For instance, to achieve the object of the fourth color light L4 generated by the fourth organic light emitting unit 433 being an orange light source, the second organic light emitting layer 435 and third organic light emitting layer 437 therein can be respectively selected as organic light emitting layers capable of emitting red light and green light. By mixing the red light and green light, an object of generating orange light can be achieved. Of course, a hole injection layer, a hole transport layer, an electron transport layer, or an electron injection layer can also be selectively comprised in the fourth organic light emitting unit 433. In other words, the outer surface of the second organic light emitting layer 435 and third organic light emitting layer 437 provided are selectively provided the hole injection layer, hole transport layer, electron transport layer, or electron injection layer, respectively.

In summary, it is appreciated that the present invention is related to an organic electroluminescent display device and more particularly to a full color organic electroluminescent display device and a method of manufacturing the same which effectively improve the light source penetration ratio and color saturation, as well as reduce power consumption and extend lifetime of elements, and further improve yield by such a simplified process.

The foregoing description is merely one embodiment of present invention and not considered as restrictive. All equivalent variations and modifications in process, method, feature, and spirit in accordance with the appended claims may be made without in any way from the scope of the invention.

### LIST OF REFERENCE SYMBOLS

10 color filter
11 substrate
13 black matrix
15 color filtering layer
151 first color photoresist
153 second color photoresist
155 third color photoresist
17 overcoat
19 barrier
20 organic electroluminescent element
200 organic electroluminescent device
21 lower electrode
23 organic electroluminescent unit
25 second electrode
30 color filter
31 light perviousness substrate
33 black matrix
35 color photoresist
351 first color photoresist
353 second color photoresist
355 third color photoresist
37 overcoat
39 barrier
40 organic electroluminescent element
400 organic electroluminescent device
41 lower electrode
43 organic electroluminescent unit
431 first organic electroluminescent unit
433 fourth organic electroluminescent unit
435 second organic electroluminescent layer
437 third organic electroluminescent layer
45 second electrode
47 first evaporation source
471 first organic light emitting material
472 second organic light emitting material
473 third organic light emitting material
477 second evaporation source
491 first mask
493 second mask
50 color filter
500 organic electroluminescent device
51 light perviousness substrate
54 hollowed part
55 color photoresist
553 second color photoresist
555 third color photoresist

1. A full color organic electroluminescent display device, comprising:
a color filter providing a first color photoresist, a second color photoresist, and a third color photoresist on an upper surface of a substrate;
at least one lower electrode provided on a partial upper surface of said color filter;
a first organic light emitting unit provided on an upper surface of said lower electrode at a vertically extended position of said first color photoresist and being able to generate a first color light;
a fourth organic light emitting unit provided on an upper surface of said lower electrode at a vertically extended position of said second color photoresist and said third color photoresist and being able to generate a fourth color light; and
at least one second electrode provided on upper surfaces of said first organic light emitting unit and said fourth organic light emitting unit.

2. The full color organic electroluminescent display device according to claim 1, wherein said first color light can pass through said first color photoresist, and said fourth color light can respectively pass through said second color photoresist and said third color photoresist, and filtered into a second color light after passing through said second color photoresist and filtered into a third color light after passing through said third color photoresist.

3. The full color organic electroluminescent display device according to claim 2, wherein said first color light is blue light, said second color light is green light, said third color light is red light, and said fourth color light is selected from one of a orange light and a yellow light.

4. The full color organic electroluminescent display device according to claim 2, wherein said first color light, second color light, and third color light are respectively selected from one of a red light, a green light, and a blue light.

5. The full color organic electroluminescent display device according to claim 1, wherein said first color photoresist of said color filter is a hollowed part.

6. The full color organic electroluminescent display device according to claim 1, wherein said color filter is a light perviousness substrate.

7. The full color organic electroluminescent display device according to claim 1, wherein said fourth organic light emitting unit comprises a second organic light emitting layer and a third organic light emitting layer, and said second organic light emitting layer and third organic light emitting layer are provided by said means of cascading.

8. The full color organic electroluminescent display device according to claim 1, wherein said fourth organic light emitting unit is adulterated with a second organic light emitting material and a third organic light emitting material.

9. The full color organic electroluminescent display device according to claim 1, wherein said color filter further comprises one of an overcoat, at least one barrier, and a combination thereof.

10. The full color organic electroluminescent display device according to claim 1, wherein said first organic light emitting unit and fourth organic light emitting unit selectively comprise one of at least one hole injection layer, at least one hole transport layer, at least one organic emitting material layer, at least one electron transport layer, at least one electron injection layer, and a combination thereof therein.

11. A method of manufacturing a full color organic electroluminescent display device, comprising the steps of:
forming at least one lower electrode on a partial upper surface of a color filter, and said color filter mainly at least providing a first photoresist, a second color photoresist, and a third color photoresist on an upper surface of a substrate;
placing a first mask at a vertically extended position of said second color photoresist and third color photoresist of said color filter;
proceeding a first evaporation process to an upper surface of said lower electrode at a vertically extended position of said first color photoresist by a first evaporation source to evaporate and form an organic light emitting layer with a first organic light emitting unit capable of generating a first color light;
placing a second mask at a vertically extended position of said first organic light emitting unit, and then proceeding a second evaporation process to an upper surface of said lower electrode at a vertically extended position of said second color photoresist and said third color photoresist by a second evaporation source to evaporate and form an organic light emitting layer with a fourth organic light emitting unit capable of generating a fourth color light; and
forming at least one second electrode on upper surfaces of said first organic light emitting unit and fourth organic light emitting unit.

12. The manufacturing method according to claim 11, wherein further comprises a step of proceeding said evaporation process of said light emitting layer of said first organic light emitting unit after proceeding said evaporation process of said light emitting layer of said fourth organic light emitting unit.

13. The manufacturing method according to claim 11, wherein said first organic light emitting unit and fourth organic light emitting unit comprise at least one of at least one hole injection layer, at least one hole transport layer, at least one electron transport layer, at least one electron injection layer, and a combination thereof therein.

14. The manufacturing method according to claim 13, further comprising the steps of: forming said hole injection layer and hole transport layer in order on an upper surface of said lower electrode; further, forming said organic light emitting layer of said first organic light emitting unit on a partial upper surface of said hole transport layer; forming said organic light emitting layer of said fourth organic light emitting unit on another partial upper surface of said hole transport layer; then forming said electron transport layer and electron injection layer in order on an upper surface of each organic light emitting layer.

15. The manufacturing method according to claim 13, wherein said organic light emitting layer of said fourth light emitting unit comprises a second organic light emitting layer and a third light emitting layer provided by cascading.

16. The manufacturing method according to claim 11, wherein said second evaporation source comprises a second organic light emitting material and a third organic light emitting material therein and forms said organic light emitting layer of said fourth organic light emitting unit by said means of adulterating and evaporating.

17. The manufacturing method according to claim 11, wherein said first color photoresist of said color filter can be a hollowed part.

18. The manufacturing method according to claim 11, wherein said first color light can pass through said first color photoresist, and said fourth color light can respectively pass through said second color photoresist and said third color photoresist, and filtered into a second color light after passing through said second color photoresist and be filtered into a third color light after passing through said third color photoresist.

19. The manufacturing method according to claim 18, wherein said first color light is blue light, said second color light is green light, said third color light is red light, and said fourth color light is selected from one of a orange light and a yellow light.
